(19) United States
(12) Patent Application Publication
(10) Pub. No.: US 2006/0113874 A1
(43) Pub. Date: Jun. 1, 2006

(54) Surface acoustic wave device package

(76) Inventor: Chi-Yen Shen, Kaohsiung City (TW)

Correspondence Address: OSTROLENK FABER GERB & SOFFEN, 1180 AVENUE OF THE AMERICAS, NEW YORK, NY, 100368403, US

(21) Appl. No.: 10/982,235

(22) Filed: Nov. 5, 2004

(51) Int. Cl. H01L 41/053

(52) U.S. Cl. 310/340

(57) ABSTRACT

A SAW device package includes a SAW die, a molding compound, and conductive leads. The SAW die includes a piezoelectric substrate having a transducer-mounting surface, transmitting and receiving transducers that are formed on the transducer-mounting surface and that have conductive connecting pads, and a cap that is formed on and that is reduced in size from the transducer-mounting surface and that cooperates with the substrate to define an embedded air cavity therebetween in such a manner that the transmitting and receiving transducers are confined in the embedded air cavity. The SAW die is encapsulated by the molding compound. The leads are connected electrically to the connecting pads and extend outwardly of the molding compound.

### BACKGROUND OF THE INVENTION

1. Field of the Invention

This invention relates to a surface acoustic wave (SAW) device package, more particularly to a SAW device package that includes a SAW die encapsulated by a molding compound.

2. Description of the Related Art

A surface acoustic wave (SAW) device normally includes a piezoelectric substrate with a transducer-mounting surface, and transmitting and receiving transducers formed on the transducer-mounting surface for transmitting and receiving surface waves propagating along the transducer-mounting surface of the substrate. Each of the transmitting and receiving transducers is in the form of a thin metal film, and includes a pair of opposing bus bars with a plurality of fingers extending from the bus bars in an interdigital manner. The SAW device is required to be enclosed within an enclosure so as to form an air cavity to permit propagation of surface acoustic wave within the cavity. Due to the cavity required between the enclosure and the transducer-mounting surface of the substrate, the SAW device cannot be directly molded with a molding compound, which is commonly used for packaging semiconductor chips, such as memory chips, to form the enclosure thereon. As a consequence, conventional ways of forming the enclosure are normally conducted by forming a casing to enclose the SAW device.

FIG. 1 illustrates a conventional SAW device that is disclosed in U.S. Pat. No. 4,845,397 and that includes a SAW die 10, a cradle 20 constraining the SAW die 10, and a casing 2 enclosing sealingly the assembly of the SAW die 10 and the cradle 20. The casing 2 includes a base 21, a cover 22 disposed over the base 21, and a spacer 23 interposed between and connected sealingly to the base 21 and the cover 22.

The manufacturing process of the aforesaid conventional SAW device is complicated and is relatively expensive. Moreover, the size of the aforesaid conventional SAW device is relatively large, and is difficult to be reduced. As a consequence, combining the conventional SAW device with a printed circuit board and electronic components to form a SAW device package, which includes a molding compound encapsulating the SAW device, the electronic components, and a portion of the printed circuit board, is not possible.

### SUMMARY OF THE INVENTION

Therefore, the object of this invention is to provide a SAW device package that is capable of overcoming the aforesaid drawbacks of the prior art.

According to the present invention, a surface acoustic wave package comprises: a SAW die including a piezoelectric substrate having a transducer-mounting surface, transmitting and receiving transducers that are formed on the transducer-mounting surface and that have conductive connecting pads, and a cap that is formed on and that is reduced in size from the transducer-mounting surface and that cooperates with the substrate to define an embedded air cavity therebetween in such a manner that the transmitting and receiving transducers are confined in the embedded air cavity; a molding compound encapsulating the SAW die; and a plurality of conductive leads connected electrically to the connecting pads and extending outwardly of the molding compound.

### BRIEF DESCRIPTION OF THE DRAWINGS

Other features and advantages of the present invention will become apparent in the following detailed description of the preferred embodiments of the invention, with reference to the accompanying drawings. In the drawings:

FIG. 1 is a fragmentary sectional view of a conventional SAW device;

FIG. 2 is a perspective view of the first preferred embodiment of a SAW device package according to this invention;

FIG. 3 is a schematic view to illustrate the configuration of a SAW die of the first preferred embodiment with a cap formed thereon;

FIG. 4 is a sectional view to illustrate the SAW die of the first preferred embodiment;

FIG. 5 is a sectional view of the second preferred embodiment according to this invention;

FIG. 6 is a sectional view of the third preferred embodiment according to this invention;

FIG. 7 is a sectional view of the fourth preferred embodiment according to this invention;

FIG. 8 is a sectional view of the fifth preferred embodiment modified from the third preferred embodiment;

FIG. 9 is a sectional view of the sixth preferred embodiment modified from the fourth preferred embodiment;

FIG. 10 is a flow diagram illustrating consecutive steps of the first preferred embodiment of a method for forming the SAW die according to this invention;

FIGS. 11 to 17 are schematic views to illustrate the consecutive steps of the first preferred embodiment of the method of this invention;

FIG. 18 is a flow diagram illustrating consecutive steps of the second preferred embodiment of the method for forming the SAW die according to this invention; and

FIGS. 19 to 21 are schematic views to illustrate the consecutive steps of the second preferred embodiment of the method of this invention.

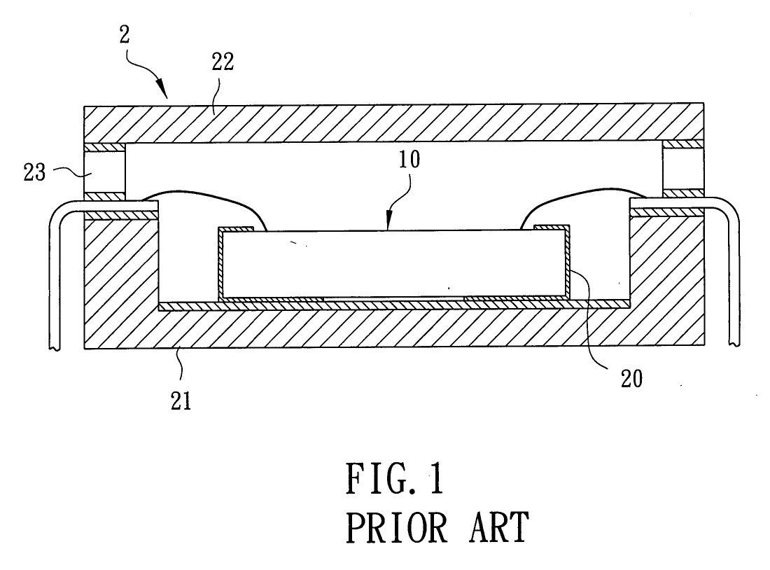

### DETAILED DESCRIPTION OF THE PREFERRED EMBODIMENTS

Before the present invention is described in greater detail, it should be noted that same reference numerals have been used to denote like elements throughout the specification.

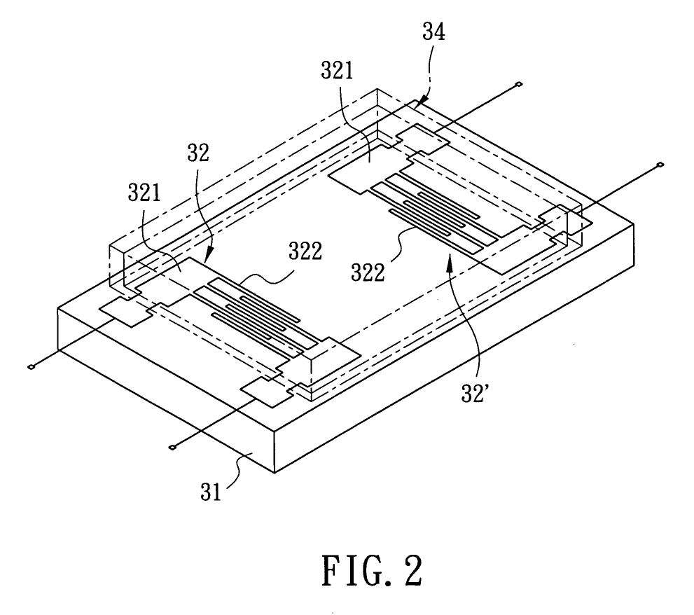

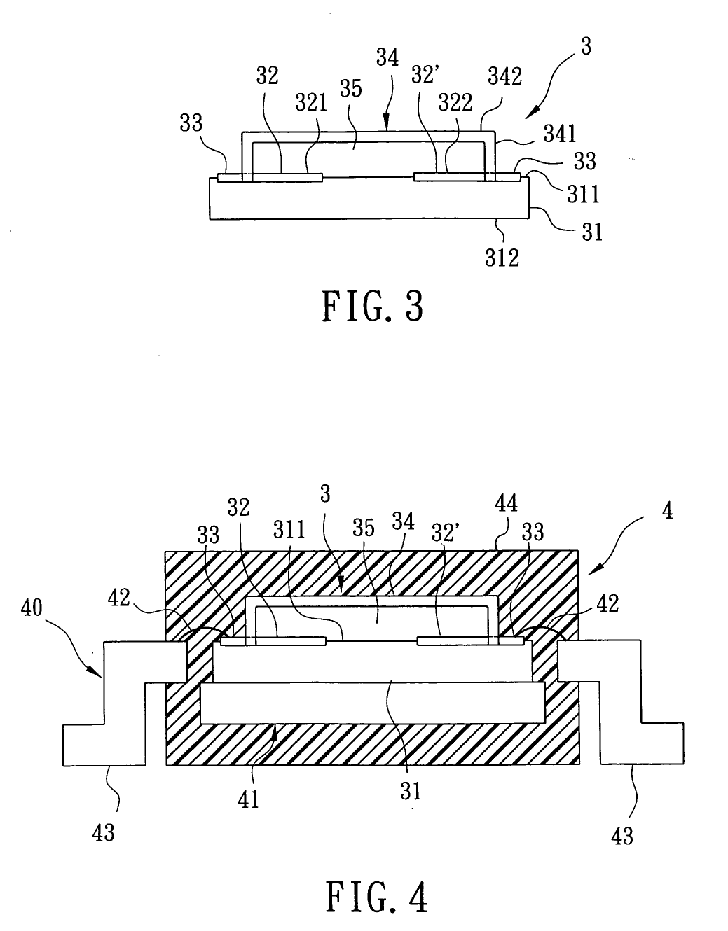

FIGS. 2 to 4 illustrate the first preferred embodiment of a surface acoustic wave (SAW) device package 4 according to this invention.

The SAW device package 4 includes: a SAW die 3 including a piezoelectric substrate 31 with a transducer-mounting surface 311, a transmitting transducer 32 formed on the transducer-mounting surface 311 for generating surface acoustic waves that propagate along the transducer-mounting surface 311, a receiving transducer 32′ formed on the transducer-mounting surface 311 for receiving the surface acoustic waves that propagate along the transducer-mounting surface 311, a plurality of conductive connecting pads 33 formed on the transducer-mounting surface 311 and connected electrically and respectively to the transmitting and receiving transducers 32, 32′, and a cap 34 that has a peripheral wall 341 which is formed on and which extends transversely and outwardly from the transducer-mounting surface 311 and which has a top opening distal from the transducer-mounting surface 311, and a cover wall 342 that is formed on the peripheral wall 341 to cover the top opening in the peripheral wall 341, the cap 34 cooperating with the substrate 31 to define an embedded air cavity 35 therebetween in such a manner that the transmitting and receiving transducers 32, 32′ are confined in the embedded air cavity 35 and that at least a portion of each of the connecting pads 33 is disposed outwardly of the embedded air cavity 35; a conductive external-connecting unit 40 that is connected electrically to the connecting pads 33 for electrically connecting the SAW die 3 to an external device (not shown); and a molding compound 44 encapsulating the SAW die 3.

In this embodiment, the cap 34 is formed on the transducer-mounting surface 311 of the substrate 31 by semiconductor processing techniques, and is made from a photo sensitive material selected from the group consisting of photoresists, epoxy resin, polyimide, benzocyclobutene, acrylic-based materials, and mixtures thereof.

Preferably, the substrate 31 is made from a piezoelectric material that is selected from the group consisting of quartz, LiNbO₃, LiTaO₃, Li₂B₄O₇, and La₃Ga₅SiO₁₄. Alternatively, the substrate 31 can be made from a non-piezoelectric material coated with a piezoelectric film, such as ZnO, Al₂O₃, and PbZrO₃.

The substrate 31 further has an external-mounting surface 312 that is opposite to the transducer-mounting surface 311. The external-connecting unit 40 includes a conductive lead frame 41 that is attached to the external-mounting surface 312 of the substrate 31 and that includes a plurality of leads 43 respectively having portions disposed outwardly of the molding compound 44. The leads 43 of the lead frame 41 are connected electrically and respectively to the connecting pads 33 through a plurality of bonding wires 42 which are encapsulated by the molding compound 44.

Each of the transmitting and receiving transducers 32, 32′ is in the form of a thin film, and includes a pair of opposing bus bars 321 with a plurality of fingers 322 extending from the bus bars 321 in an interdigital manner.

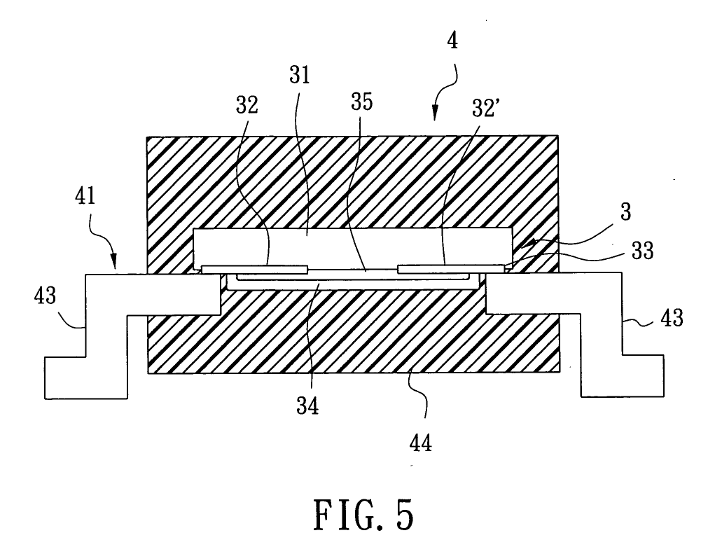

FIG. 5 illustrates the second preferred embodiment of the SAW device package 4 according to this invention. The SAW device package 4 of this embodiment differs from the previous embodiment in that the leads 43 of the lead frame 41 are directly and respectively connected to the connecting pads 33 without using the bonding wires 42.

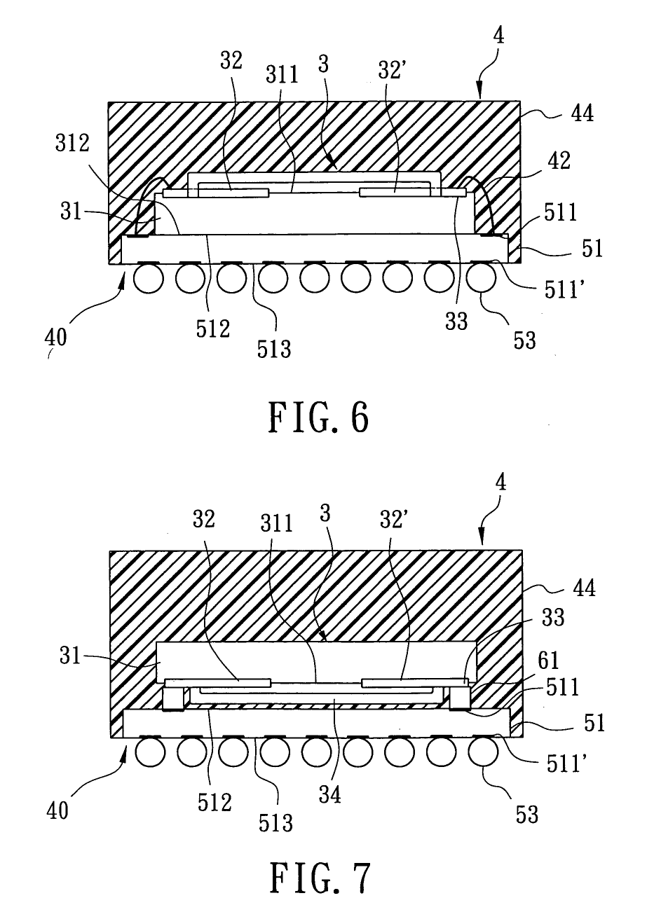

FIG. 6 illustrates the third preferred embodiment of the SAW device package 4 according to this invention. The SAW package 4 of this embodiment differs from the first embodiment in that the external-connecting unit 40 includes a printed circuit board 51 that is inlaid in the molding compound 44, and that has an inner surface 512 which is attached to the external-mounting surface 312 of the substrate 31, an outer surface 513 which is opposite to the inner surface 512, a plurality of conductive inner contacts 511 which are formed on the inner surface 512 and which are connected electrically and respectively to the connecting pads 33 through the bonding wires 42, a plurality of outer contacts 511′ which are formed on the outer surface 513 of the printed circuit board 51, and a plurality of conductive outer bumps 53 which are connected electrically to the outer contacts 511′, and which protrude outwardly of the molding compound 44. The printed circuit board 51 is covered by the molding compound 44 in such a manner that the outer surface 513 of the printed circuit board 51 is exposed therefrom.

FIG. 7 illustrates the fourth preferred embodiment of the SAW device package 4 according to this invention. The SAW device package 4 of this embodiment differs from the second embodiment in that the external-connecting unit 40 includes a printed circuit board 51 that is inlaid in the molding compound 44, and that has an inner surface 512 which confronts the transducer-mounting surface 311 of the substrate 31, an outer surface 513 which is opposite to the inner surface 512, a plurality of conductive contacts 511 which are formed on the inner surface 512 and which are connected electrically and respectively to the connecting pads 33 through a plurality of conductive inner bumps 61, and a plurality of conductive outer bumps 53 which are formed on the outer surface 513, and which protrude outwardly of the molding compound 44.

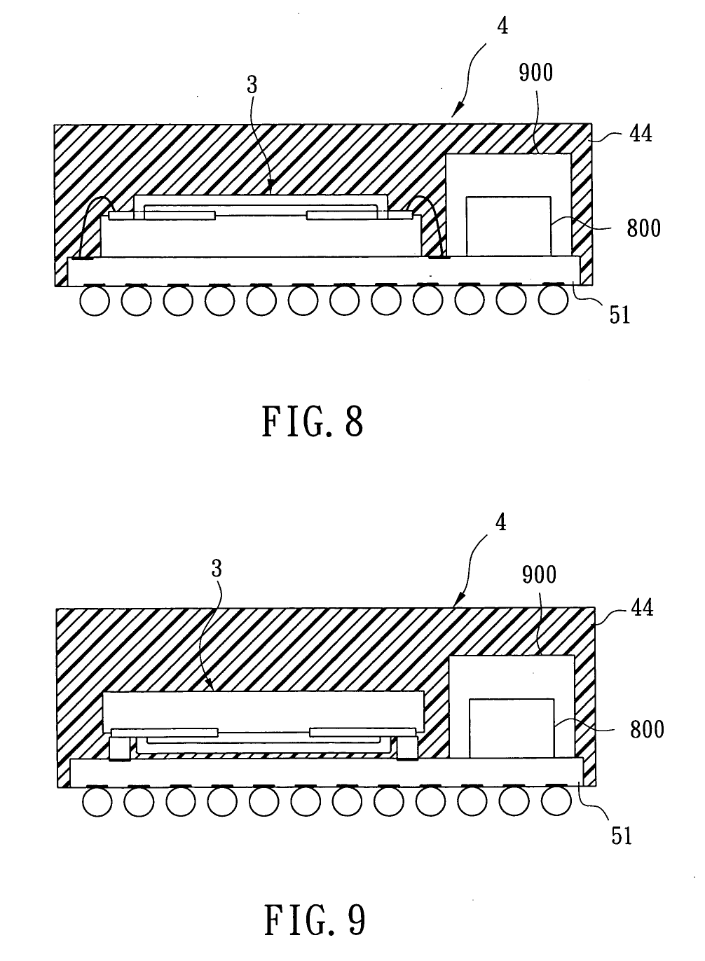

FIG. 8 illustrates the fifth preferred embodiment of the SAW device package 4 according to this invention. The SAW device package 4 of this embodiment is modified from the third embodiment by further including electronic components 800, 900, such as a resistor and a capacitor. The electronic components 800, 900 are mounted on the printed circuit board 51 and are encapsulated by the molding compound 44.

FIG. 9 illustrates the sixth preferred embodiment of the SAW device package 4 according to this invention. The SAW device package 4 of this embodiment is modified from the fourth embodiment by further including electronic components 800, 900 that are mounted on the printed circuit board 51 and that are encapsulated by the molding compound 44.

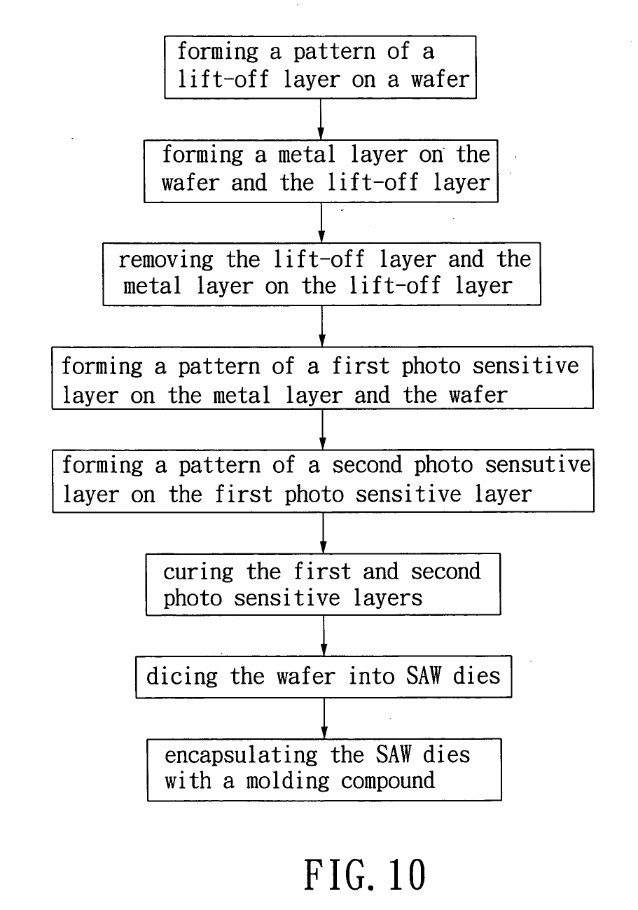

FIG. 10 illustrates the consecutive steps of the first preferred embodiment of a method which involves using lift-off techniques for forming the SAW die 3 according to this invention.

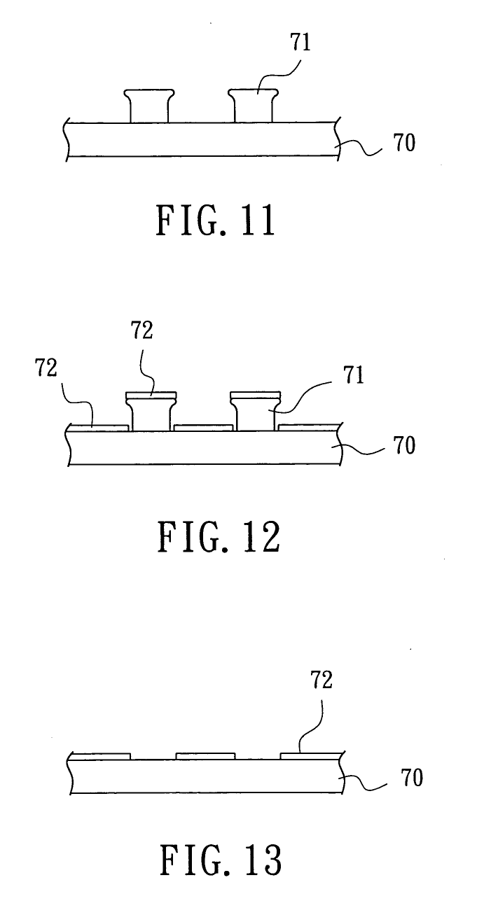

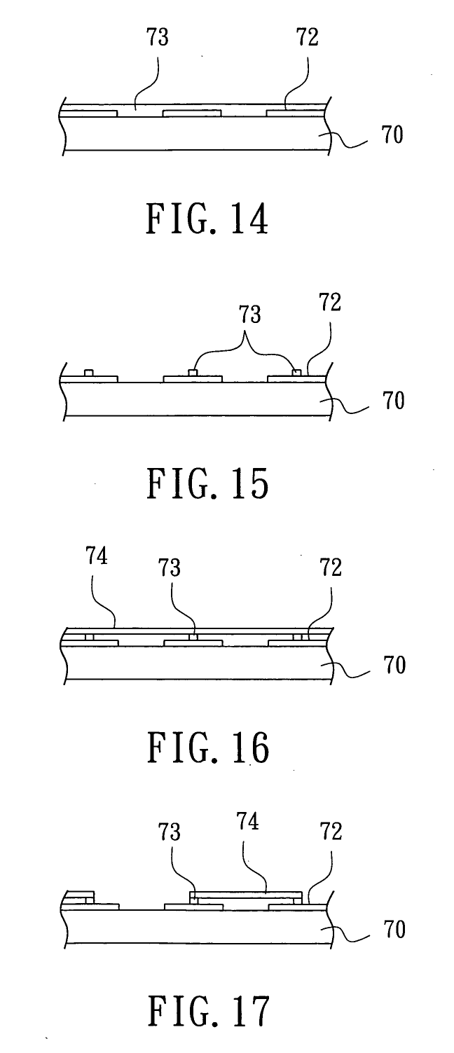

Referring to FIGS. 11 to 17, the method of the first embodiment includes the steps of: cleaning a wafer 70 having a wafer surface, the wafer surface defining the transducer-mounting surface 311 of the substrate 31 of the SAW die 3; forming a pattern of lift-off layer 71 on the wafer surface of the wafer 70 (see FIG. 11) through lithography techniques; forming a metal layer 72 on the wafer surface of the wafer 70 and the lift-off layer 71 through metallization techniques (see FIG. 12) ; removing the lift-off layer 71 and the metal layer 72 on the lift-off layer 71 by dissolving the lift-off layer 71 in a solution so as to form a pattern of the metal layer 72 (see FIG. 13), which forms the transmitting and receiving transducers 32, 32′ of the SAW die 3, on the wafer surface of the wafer 70; forming a first photo sensitive layer 73 on the wafer surface of the wafer 70 and the metal layer 72 (see FIG. 14); forming a pattern of the first photo sensitive layer 73, which forms the peripheral wall 341 of the cap 34 of the SAW die 3, on the metal layer 72 and the wafer surface of the wafer 70 (see FIG. 15) through lithography techniques; forming a pattern of a second photo sensitive layer 74 (see FIG. 16), which forms the cover wall 342 of the cap 34 of the SAW die 3, on the first photo sensitive layer 73 through lithography techniques (see FIG. 17) ; curing the first and second photo sensitive layers 73, 74; dicing the wafer 70 into SAW dies 3. The SAW dies 3 thus formed are subsequently subjected to encapsulation using the molding compound 44. Note that each of the first and second photo sensitive layers 73, 74 is in the form of a dry film prior to be formed on the wafer 70. The dry film is subsequently processed to form a desired pattern using lithography techniques.

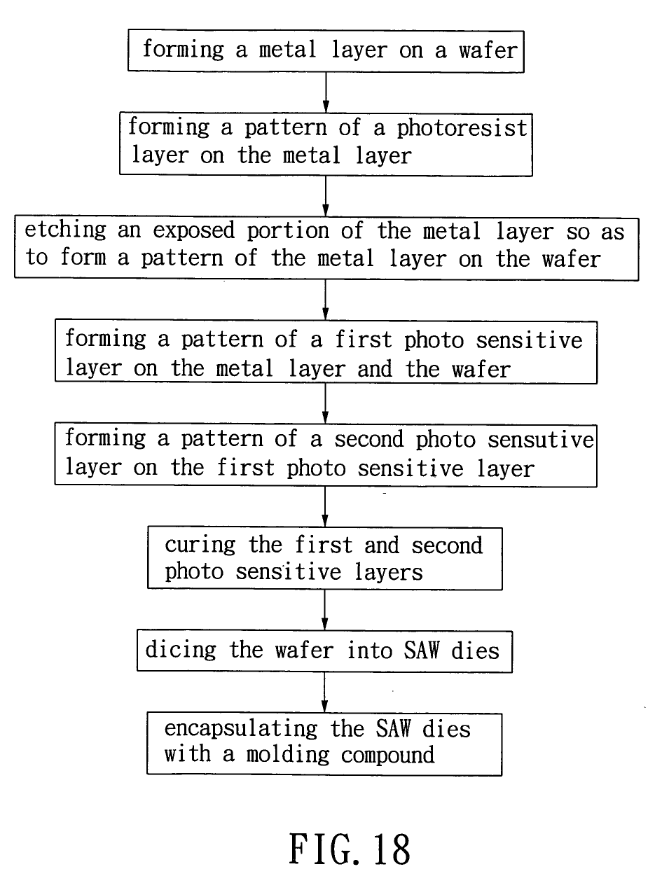

FIG. 18 illustrates the consecutive steps of the second preferred embodiment of the method for forming the SAW die 3 according to this invention. The method of this embodiment differs from the previous embodiment in that the pattern of the metal layer 72 is formed by metal etching techniques instead of the lift-off techniques.

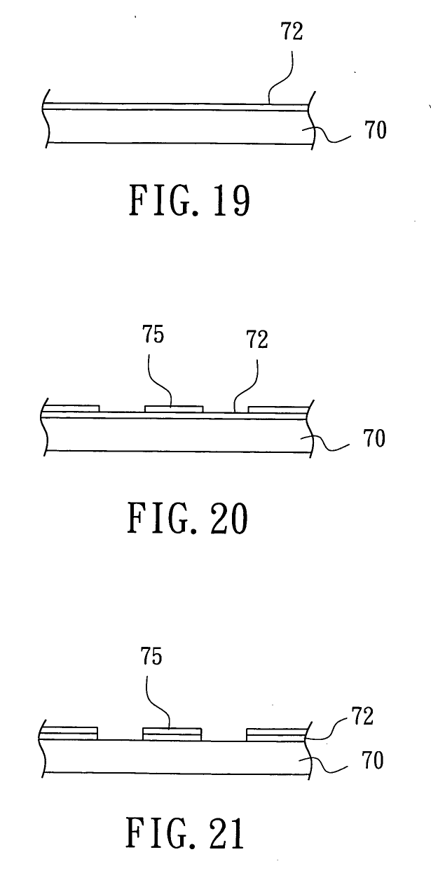

In this embodiment, the pattern of the metal layer 72 is formed by forming the metal layer 72 on the wafer surface of the wafer 70 (see FIG. 19) through metallization techniques after the wafer 70 is cleaned, forming a pattern of a photoresist layer 75 on the metal layer 72 through lithography techniques (see FIG. 20), and wet etching an exposed portion of the metal layer 72 that is exposed from the photoresist layer 75 so as to form the pattern of the metal layer 72 on the wafer surface of the wafer 70 (see FIG. 21). The photoresist layer 75 is subsequently removed from the metal layer 72 so as to form into a structure similar to that of FIG. 13 for subsequent processing steps of forming the cap 34 on the metal layer 72 which are similar to those of the first preferred embodiment.

With the inclusion of the cap 34, which is formed on the substrate 31 by semiconductor processing techniques, in the SAW die 3 of the SAW device package 4 of this invention, the SAW die 3 can be directly molded with the molding compound 44, thereby eliminating the aforesaid drawbacks associated with the prior art. Moreover, the SAW device package 4 thus formed can be encapsulated with other electronic components to form a hybrid package for the purposes of product miniaturization and reducing manufacturing costs.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

I claim:

1. A surface acoustic wave (SAW) device package comprising:
a SAW die including a piezoelectric substrate having a transducer-mounting surface, transmitting and receiving transducers that are formed on said transducer-mounting surface and that have conductive connecting pads, and a cap that is formed on and that is reduced in size from said transducer-mounting surface and that cooperates with said substrate to define an embedded air cavity therebetween in such a manner that said transmitting and receiving transducers are confined in said embedded air cavity;
a molding compound encapsulating said SAW die; and
a plurality of conductive leads connected electrically to said connecting pads and extending outwardly of said molding compound.

2. The SAW device package of claim 1, wherein said cap has a peripheral wall that is formed on said transducer-mounting surface of said substrate through semiconductor processing techniques, and that defines a top opening, and a cover wall that is formed on said peripheral wall and that covers said top opening.

3. The SAW device package of claim 2, wherein said peripheral wall of said cap is made from a photo sensitive material that is selected from the group consisting of photoresists, epoxy resin, polyimide, benzocyclobutene, acrylic-based materials, and mixtures thereof.

4. The SAW device package of claim 1, further comprising a plurality of conductive bonding wires that are encapsulated by said molding compound, each of said bonding wires interconnecting a respective one of said leads and a respective one of said connecting pads.

5. The SAW device of claim 1, wherein said substrate is made from a material selected from the group consisting of quartz, LiNbO₃, LiTaO₃, Li₂B₄O₇, and La₃Ga₅SiO₁₄.

6. The SAW device package of claim 1, wherein said substrate is made from a non-piezoelectric material coated with a piezoelectric film that is selected from the group consisting of ZnO, Al₂O₃, PbZrO₃, and mixtures thereof.

7. A SAW device package comprising:
a SAW die including a piezoelectric substrate having a transducer-mounting surface, transmitting and receiving transducers that are formed on said transducer-mounting surface and that have conductive connecting pads, and a cap that is formed on and that is reduced in size from said transducer-mounting surface and that cooperates with said substrate to define an embedded air cavity therebetween in such a manner that said transmitting and receiving transducers are confined in said embedded air cavity;
a printed circuit board having opposite inner and outer surfaces and formed with conductive inner contacts on said inner surface and conductive outer contacts on said outer surface, each of said inner contacts being connected electrically to a respective one of said connecting pads;
a molding compound encapsulating said SAW die and covering said printed circuit board in such a manner that said outer surface of said printed circuit board is exposed therefrom; and
a plurality of conductive outer bumps formed on said outer contacts and protruding outwardly of said molding compound therefrom.

8. The SAW device package of claim 7, wherein said cap has a peripheral wall that is formed on said transducer-mounting surface by depositing a photo sensitive material thereon through semiconductor processing techniques, and that defines a top opening, and a cover wall that is formed on said peripheral wall and that covers said top opening.

9. The SAW device package of claim 8, wherein said photo sensitive material is selected from the group consisting of photoresists, epoxy resin, polyimide, benzocyclobutene, acrylic-based materials, and mixtures thereof.

10. The SAW device package of claim 7, further comprising a plurality of bonding wires that are encapsulated by said molding compound, each of said bonding wires interconnecting a respective one of said inner contacts and a respective one of said connecting pads.

11. The SAW device package of claim 10, further comprising at least an electronic component that is encapsulated by said molding compound and that is mounted on said printed circuit board.

12. The SAW device package of claim 7, further comprising a plurality of inner bumps that are encapsulated by said molding compound, each of said inner bumps being formed on a respective one of said connecting pads and each of which is connected electrically to a respective one of said inner contacts.

13. The SAW device package of claim 12, further comprising at least an electronic component that is encapsulated by said molding compound and that is mounted on said printed circuit board.

14. The SAW device package of claim 7, wherein said substrate is made from a material selected from the group consisting of quartz, LiNbO₃, LiTaO₃, Li₂B₄O₇, and La₃Ga₅SiO₁₄.

15. The SAW device package of claim 7, wherein said substrate is made from a non-piezoelectric material coated with a piezoelectric film that is selected from the group consisting of ZnO, Al₂O₃, PbZrO₃, and mixtures thereof.
